(19) United States
(12) Patent Application Publication
(10) Pub. No.: US 2025/0042723 A1
(43) Pub. Date: Feb. 6, 2025

(54) PROTECTIVE COATING FOR COPPER SURFACE IN SENSOR

(71) Applicant: Texas Instruments Incorporated, Dallas, TX (US)

(72) Inventors: Jeffrey S. Solas, Iloilo City (PH); Rujuta Munje, McKinney, TX (US); Sophia Delpak, Richardson, TX (US)

(21) Appl. No.: 18/362,103

(22) Filed: Jul. 31, 2023

(51) Int. Cl. B81B 3/00; B81C 1/00

(52) U.S. Cl. CPC B81B 3/0075; B81C 1/00658; B81B 2201/02; B81B 2203/0315; B81C 2201/0173

(57) ABSTRACT

A microelectronic device includes a copper structure over an electronic component. The copper structure includes copper having an average grain size greater than 1 micron. The copper structure has a corrosion barrier, which includes primarily cuprous oxide, directly on the copper. The corrosion barrier is exposed at an exterior surface. The microelectronic device is formed by plating copper over a substrate of the microelectronic device. The copper structure with the corrosion barrier is annealed at a temperature of 125° C. to 200° C. in a non-reducing ambient.

### TECHNICAL FIELD

This disclosure relates to the field of microelectronic devices. More particularly, but not exclusively, this disclosure relates to microelectronic devices having exposed copper structures.

### BACKGROUND

Some microelectronic devices have copper structures that are exposed on the devices. The copper structures may provide mechanical support or spatial isolation for a sensor, for example. A significant challenge with this design is the potential for corrosion of the exposed copper surface. Copper is susceptible to environmental factors such as moisture, oxygen, and certain chemicals, which can lead to the corrosion of the copper surface over time.

### SUMMARY

The present disclosure introduces a microelectronic device including a copper structure over an electronic component. The copper structure includes copper having an average grain size greater than 1 micron. The copper structure includes a corrosion barrier directly on the copper. The corrosion barrier is exposed at an exterior surface of the microelectronic device. The corrosion barrier includes primarily cuprous oxide.

The microelectronic device is formed by plating copper over a substrate of the microelectronic device to form the copper structure. The copper structure with the corrosion barrier is annealed at a temperature of 125° C. to 200° C. in a non-reducing ambient. The corrosion barrier is exposed at an exterior surface of the completed microelectronic device.

### BRIEF DESCRIPTION OF THE FIGURES

FIG. 1A and FIG. 1B are a perspective and a cross-section of an example microelectronic device having a copper structure.

FIG. 2A through FIG. 2I are cross sections of the microelectronic device of FIG. 1A and FIG. 1B, depicted in stages of an example method of formation.

FIG. 3A and FIG. 3B are edge representations of microphotographs of electroplated copper, before and after annealing.

FIG. 4A through FIG. 4D are cross sections of another example microelectronic device, depicted in stages of another example method of formation.

### DETAILED DESCRIPTION

The present disclosure is described with reference to the attached figures. The figures are not drawn to scale and they are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

In addition, although some of the embodiments illustrated herein are shown in two dimensional views with various regions having depth and width, it should be clearly understood that these regions are illustrations of only a portion of a device that is actually a three dimensional structure. Accordingly, these regions will have three dimensions, including length, width, and depth, when fabricated on an actual device. Moreover, while the present invention is illustrated by embodiments directed to active devices, it is not intended that these illustrations be a limitation on the scope or applicability of the present invention. It is not intended that the active devices of the present invention be limited to the physical structures illustrated. These structures are included to demonstrate the utility and application of the present invention to presently preferred embodiments.

A microelectronic device includes an electronic component in a substrate. A copper structure is formed over the electronic component. The copper structure includes primarily copper, and is formed by a plating process. After the plating process is completed, and before any significant annealing of the copper takes place, an average grain size of the copper is less than 1 micron. A corrosion barrier of the copper structure is formed directly on the copper. The corrosion barrier includes primarily cuprous oxide. The copper structure is annealed at a temperature of 125° C. to 200° C. in a non-reducing ambient. The substrate and the copper structure are packaged to provide the microelectronic device. The corrosion barrier is exposed at an exterior surface of the microelectronic device.

For the purposes of this disclosure, a structure or component that is disclosed as including “primarily” a substance has more than 50 percent, by weight, of that substance. For example, an interconnect that is disclosed to include primarily copper has more than 50 percent, by weight, of the element copper.

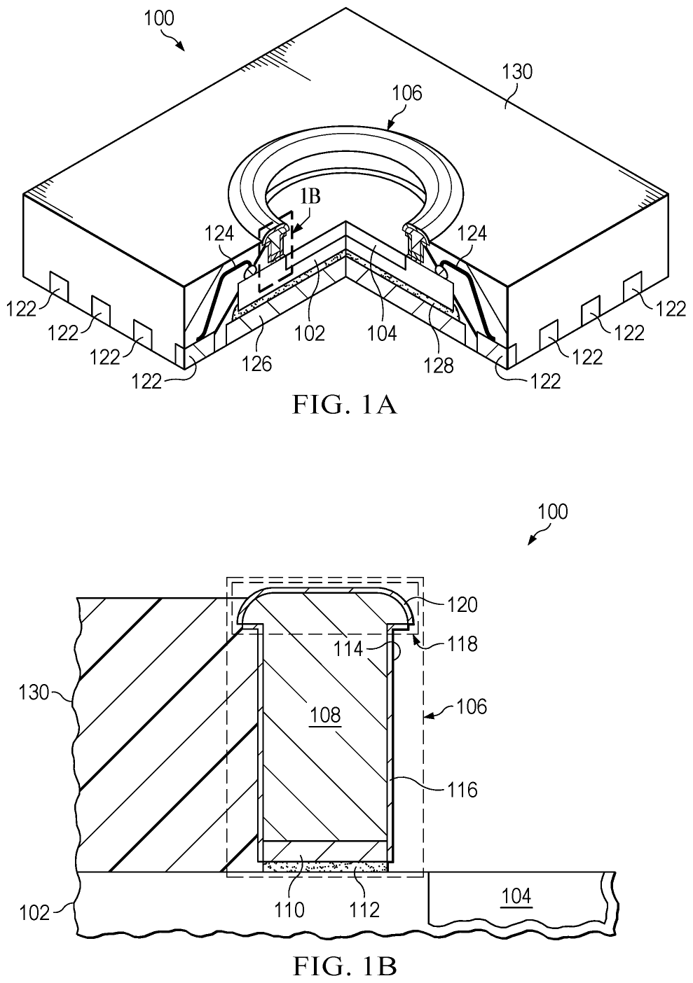

FIG. 1A and FIG. 1B are a perspective and a cross-section of an example microelectronic device having a copper structure. The microelectronic device 100 includes a substrate 102. The substrate 102 may be manifested as an integrated circuit, a microelectrical mechanical system (MEMS) device, an electro-optical device, or a microfluidic device, by way of example. The substrate 102 may include primarily silicon or other semiconductor material, sapphire, glass, ceramic, or polymer. The substrate 102 includes an electronic component 104. The electronic component 104 may be manifested as a sensor, such as a humidity sensor, a pressure sensor, a temperature sensor, an optical sensor, an infrared sensor, a chemical sensor, or a microphone, by way of example.

The microelectronic device 100 includes a copper structure 106 over the electronic component 104. Details of the copper structure 106 are shown in FIG. 1B. The copper structure 106 of this example includes a cavity enclosure 108 of electroplated copper, so that the copper structure 106 includes primarily copper. The cavity enclosure 108 may also include carbon distributed in the copper, as a result of organic additives in a copper plating bath used to electroplate the copper. An average carbon content of the copper structure 106 is less than 20 parts per million (ppm) by weight.

The cavity enclosure 108 is connected to the substrate 102 through a seed layer 110 and an adhesion layer 112. The seed layer 110 includes primarily copper, and may consist essentially of copper. The adhesion layer 112 includes one or more metals that have high adhesion to the substrate 102 and to the seed layer 110. The adhesion layer 112 may include titanium tungsten alloy, titanium, or chromium, by way of example.

The copper structure 106 includes a corrosion barrier 114 directly on the copper of the cavity enclosure 108. The corrosion barrier 114 includes primarily cuprous oxide (Cu₂O). The corrosion barrier 114 may be 0.5 nanometers to 3 nanometers thick. The corrosion barrier 114 is exposed at an exterior surface 116 of the microelectronic device 100. In this example, the exterior surface 116 faces a region that is laterally surrounded by the cavity enclosure 108.

In this example, the copper structure 106 also includes a cap portion 118 that extends laterally past vertical sidewalls of the copper structure 106. The cap portion 118 may provide mechanical protection and durability for the cavity enclosure 108. A metal cap layer 120 of the copper structure 106 may be formed on the copper of the cavity enclosure 108. In this example, the metal cap layer 120 may include primarily nickel. In other versions of this example, the metal cap layer 120 may include chromium, gold, platinum, cobalt, palladium, or a combination thereof, by way of example. The metal cap layer 120 may provide corrosion protection and scratch resistance for the copper structure 106. The metal cap layer 120 may be 0.5 microns to 5 microns thick, by way of example.

The microelectronic device 100 includes leads 122 that are electrically connected to the substrate 102 through wire bonds 124. The microelectronic device 100 may include a die pad 126, to which the substrate 102 is attached through a die attach material 128.

The microelectronic device 100 may include an encapsulation material 130 that encapsulates the substrate 102 and surrounds the copper structure 106. The encapsulation material 130 may include a polymer material such as epoxy. The encapsulation material 130 may also include filler particles, such as silicon dioxide particles, not specifically shown, to reduce an average thermal expansion coefficient of the encapsulation material 130. The cap portion 118 of the copper structure 106 may advantageously facilitate keeping the encapsulation material 130 out of the region that is laterally surrounded by the cavity enclosure 108.

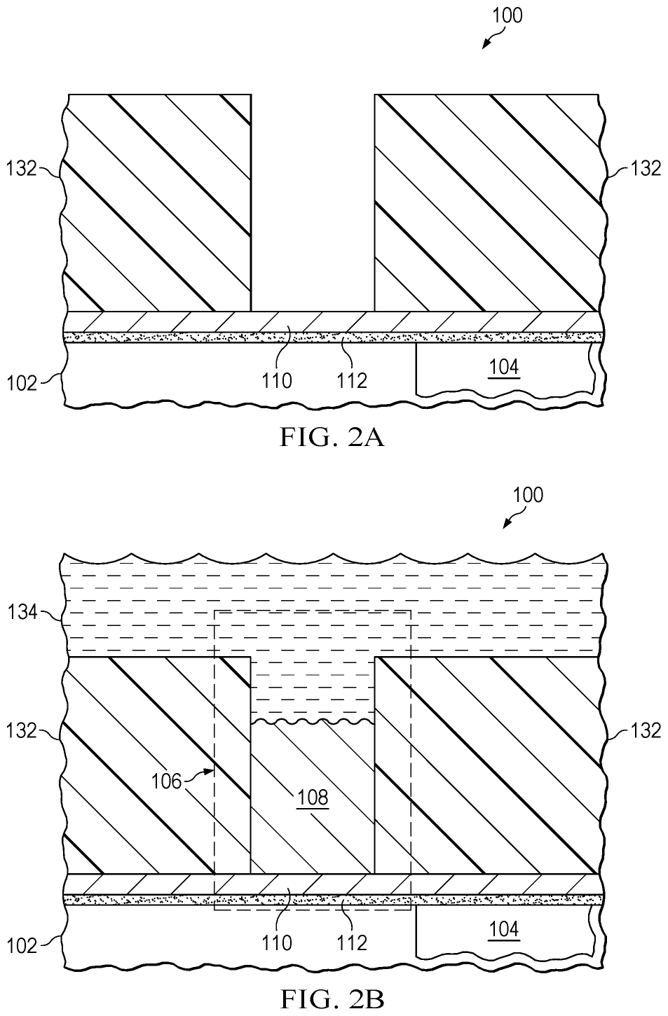

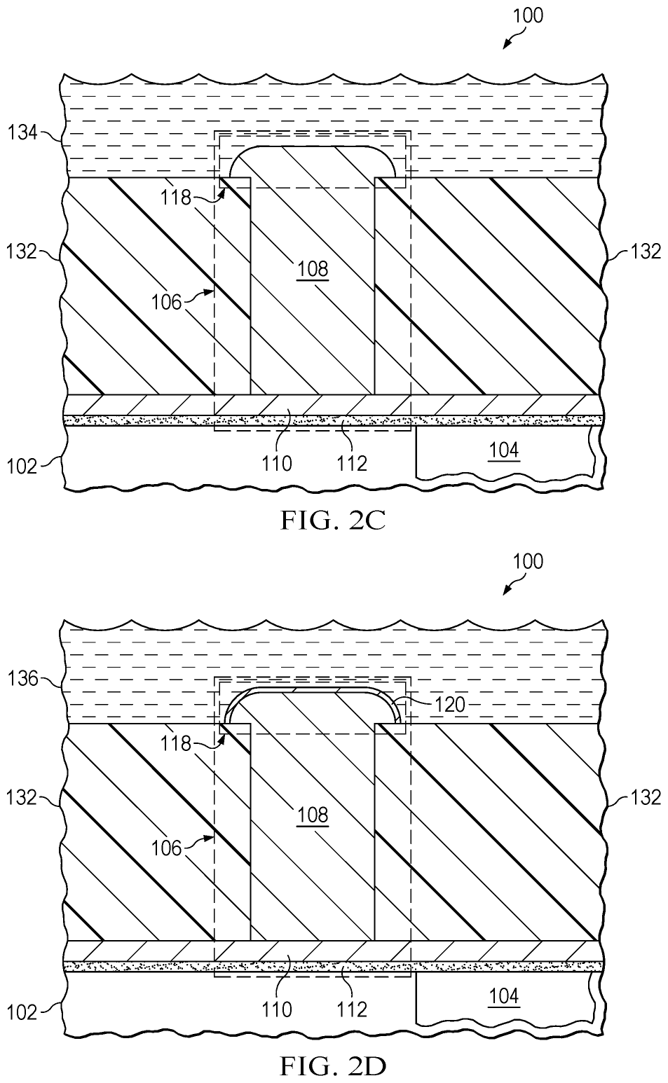

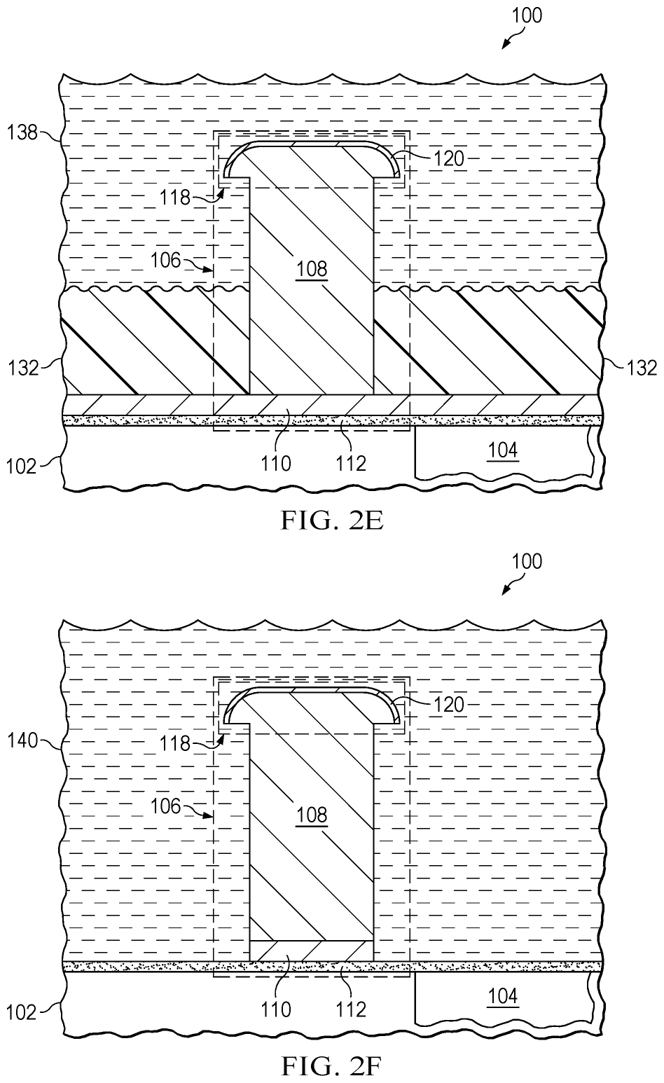

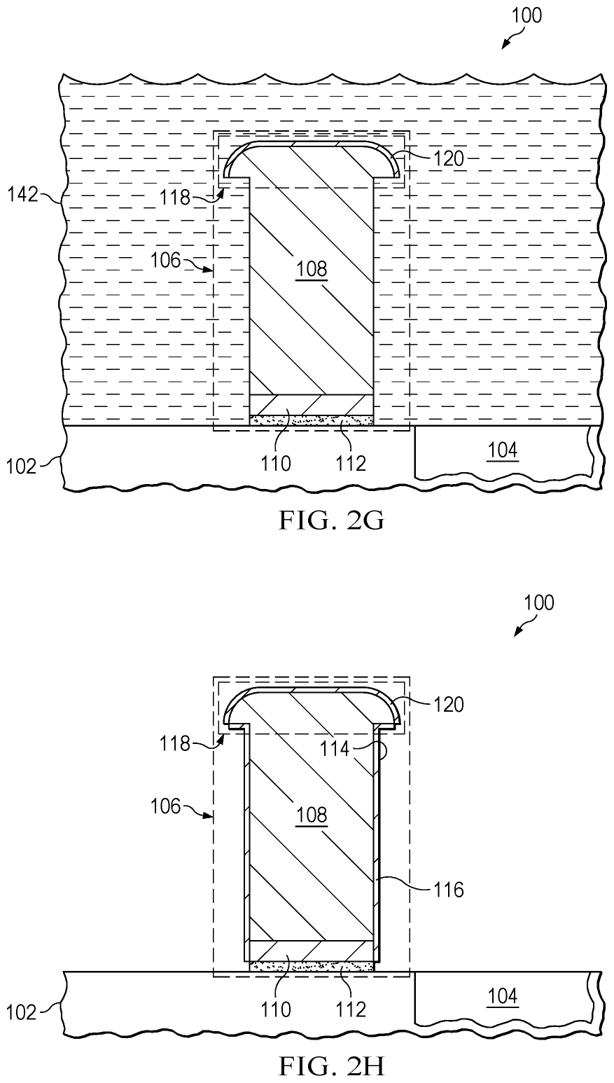

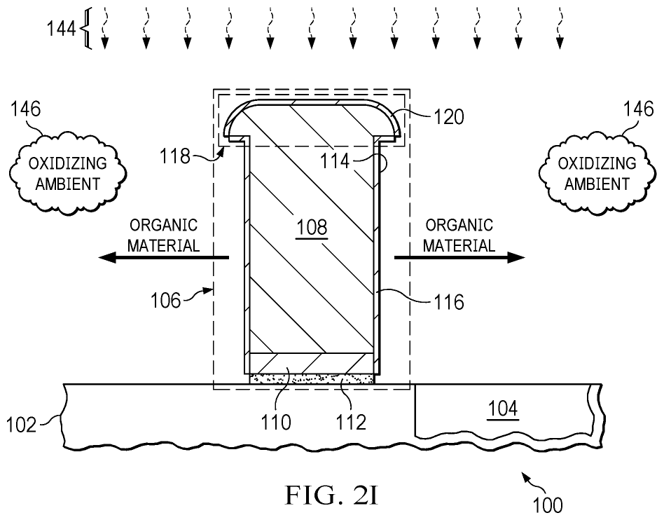

FIG. 2A through FIG. 2I are cross sections of the microelectronic device 100 of FIG. 1A and FIG. 1B, depicted in stages of an example method of formation. Referring to FIG. 2A, the substrate 102 may be manifested as a semiconductor wafer, MEMS substrate, or other format containing additional microelectronic devices. The adhesion layer 112 is formed on the substrate 102 by a physical vapor deposition (PVD) process, such as a sputter process. The adhesion layer 112 may be 5 nanometers to 50 nanometers thick, by way of example. The seed layer 110 is formed on the adhesion layer 112 by a PVD process, such as a sputter process or an evaporation process. The seed layer 110 is sufficiently thick to provide uniform electroplating across the substrate 102. The seed layer 110 may be 100 nanometers to 1 micron, by way of example.

A plating mask 132 is formed over the seed layer 110, exposing the seed layer 110 in the area for the cavity enclosure 108 of FIG. 2B. The plating mask 132 may include photoresist, formed by a spin-coat process. Multiple iterations of spin coating and baking may be necessary to attain a desired thickness of the plating mask 132. The spin coat process may advantageously enable attainment of the desired thickness within a tight range. In another version of this example, the photoresist may be formed by a dry film process, advantageously attaining the desired thickness in one application. In a further version of this example, the photoresist may be formed by an additive process such as microdispensing or material jetting, which may advantageously reduce consumption of photoresist while enabling attainment of the desired thickness within a tight range.

The photoresist may be a positive tone photoresist or a negative tone photoresist. The photoresist is subsequently patterned by a photolithographic process, including exposure using a photomask and developing, to provide the plating mask 132. An asher process may be performed to remove any residue from the seed layer 110 in the area for the cavity enclosure 108.

Referring to FIG. 2B, the microelectronic device 100 is immersed in a copper plating bath 134. The copper plating bath 134 includes copper ions in an aqueous solution. The copper plating bath 134 also includes organic additives, such as suppressors, accelerators, sometimes referred to as brighteners, and levelers. By way of example, the suppressors may include polyethylene glycol (PEG) or polypropylene glycol (PPG). The accelerators may include sulfur-based organic molecules such as bis(sodiumsulfopropyl) disulfide (SPS). The levelers may include thiourea, benzotriazole (BTA), or Janus Green B (C₃₀H₃₁ClN₆). The organic additives may advantageously enable more uniform electroplating of the copper compared to plating without the additives.

Electric current is flowed from a copper anode, not specifically shown, through the copper plating bath 134, to the seed layer 110, causing copper to be electroplated in the area exposed by the plating mask 132, thereby forming the cavity enclosure 108. FIG. 2B depicts the cavity enclosure 108 partway to completion. As the copper is electroplated on the cavity enclosure 108, a portion of the organic additives are incorporated into the cavity enclosure 108. The organic additives tend to segregate at grain boundaries of the copper, inhibiting grain growth in the copper, resulting in an average grain size of the copper that is less than 1 micron. Incorporation of the organic additives into the cavity enclosure 108 may result in an average carbon content of the copper structure 106, immediately after plating the copper, which is more than 100 ppm by weight.

Referring to FIG. 2C, electroplating the copper is continued so that the cavity enclosure 108 extends above the plating mask 132. As the copper is electroplated on the cavity enclosure 108 above the plating mask 132, the copper is electroplated on lateral surface of the cavity enclosure 108 exposed by the plating mask 132, to form the cap portion 118 of the copper structure 106. FIG. 2C depicts the cavity enclosure 108 at completion.

Referring to FIG. 2D, the microelectronic device 100 is immersed in a nickel plating bath 136. Electric current is flowed from a nickel anode, not specifically shown, through the nickel plating bath 136, to the cavity enclosure 108, causing nickel to be electroplated on the cap portion 118 of the copper structure 106, thereby forming the metal cap layer 120.

Referring to FIG. 2E, the plating mask 132 is removed. The plating mask 132 may be removed by a wet strip process using a photoresist stripper 138, such as n-methyl pyrrolidone (NMP). FIG. 2E depicts removal of the plating mask 132 partway to completion. Alternatively, the plating mask 132 may be removed by a downstream asher process.

Referring to FIG. 2F, the seed layer 110 is removed where exposed by the cavity enclosure 108. The seed layer 110 may be removed by a wet etch process using an aqueous copper etch solution 140. The aqueous copper etch solution 140 may include a dilute mixture of sulfuric acid and hydrogen peroxide, a dilute solution of nitric acid, a mixture of hydrochloric acid and ferric chloride, or a mixture of ammonium hydroxide and hydrogen peroxide, by way of example.

Referring to FIG. 2G, the adhesion layer 112 is removed where exposed by the seed layer 110. The adhesion layer 112 may be removed by a wet etch process using an aqueous etch solution 142. In versions of this example in which the adhesion layer 112 includes titanium tungsten alloy, the aqueous etch solution 142 may include hydrogen peroxide at 30° C. to 50° C. In versions of this example in which the adhesion layer 112 includes titanium, the aqueous etch solution 142 may include dilute hydrofluoric acid, or a mixture of ammonium hydroxide and hydrogen peroxide. In versions of this example in which the adhesion layer 112 includes chromium, the aqueous etch solution 142 may include a mixture of ceric ammonium nitrate and perchloric acid.

Removal of the seed layer 110 and the adhesion layer 112 may also remove a portion or all of copper oxide on exposed surfaces of the cavity enclosure 108. Oxidizing reagents used in the removal of the seed layer 110 and the adhesion layer 112 may oxidize copper at the exposed surfaces of the cavity enclosure 108, forming cuprous oxide there.

Referring to FIG. 2H, the microelectronic device 100 is rinsed and dried, and subsequently exposed to air. After exposure to air, a corrosion barrier 114 is present on the exterior surface 116 of the microelectronic device 100. The corrosion barrier 114 includes primarily cuprous oxide, and may be 0.5 nanometers to 2 nanometers thick.

Referring to FIG. 2I, the microelectronic device 100 is heated by an anneal process 144 to 125° C. to 200° C. in a non-reducing ambient 146, implemented as an oxidizing ambient 146 in this example, as depicted schematically in FIG. 2I. The anneal process 144 may be an oven process, a radiant process, a hot plate process, or a furnace process, for example. The oxidizing ambient 146 may be implemented as air, oxygen, or other oxygen-containing gas. The microelectronic device 100 is heated for 20 minutes to 45 minutes by the anneal process 144. The anneal process 144 is performed within 4 hours after removal of the adhesion layer 112, to avoid corrosion of the copper in the cavity enclosure 108 by humidity in room air. It was found that annealing for less than 20 minutes was ineffective in transforming the corrosion barrier 114 to become sufficiently impermeable to moisture to enable the microelectronic device 100 to pass the high temperature and high humidity stress tests. Annealing for more than 45 minutes provides no additional benefit, and disadvantageously increases cycle time and reduces throughput of the anneal process 144.

During the anneal process 144, organic material, depicted schematically in FIG. 2I, in the cavity enclosure 108 diffuses out of the copper structure 106, into the oxidizing ambient 146. As a result of the diffusion of the organic material from the cavity enclosure 108, the average carbon content of the copper structure 106 may drop from more than 100 ppm by weight to less than 20 ppm by weight, during the anneal process 144.

A significant amount of the organic material diffusing from the cavity enclosure 108 may have been segregated at the grain boundaries of the copper in the cavity enclosure 108. Reduction of the organic material at the grain boundaries may result in grain growth in the copper. The average grain size of the copper may grow from less than 1 micron to greater than 1 micron, during the anneal process 144.

The corrosion barrier 114 becomes more contiguous and more impermeable to moisture during the anneal process 144. As a result of the oxygen in the oxidizing ambient 146, the corrosion barrier 114 may increase in thickness from an as-formed range of 0.5 nanometers to 2 nanometers thick to a final range of 1 nanometer to 3 nanometers thick.

Heating the microelectronic device 100 to at least 125° C. during the anneal process 144 advantageously results in the corrosion barrier 114 becoming sufficiently impermeable to moisture to enable the microelectronic device 100 to pass high temperature and high humidity stress tests. Maintaining the microelectronic device 100 to a temperature no greater than 200° C. during the anneal process 144 advantageously maintains contiguous integrity of the corrosion barrier 114. Copper has a thermal expansion coefficient that is 3 to 5 times a thermal expansion coefficient of cuprous oxide. During the anneal process 144 and subsequent cooldown, it was found that heating the microelectronic device 100 above 200° C. causes loss of integrity of the corrosion barrier 114 and failure during high temperature and high humidity stress tests.

After the anneal process 144 is completed, formation of the microelectronic device 100 is continued to form the packaged microelectronic device 100 of FIG. 1A. Elements of the packaged microelectronic device 100 are shown in, and disclosed in reference to, FIG. 1A. The microelectronic device 100 is singulated. After singulation, the microelectronic device 100 is attached to the die pad 126. The wire bonds 124 are formed, electrically connecting the substrate 102 to the leads 122. The encapsulation material 130 is formed on the substrate 102 and leads 122, surrounding the copper structure 106. The corrosion barrier 114 advantageously protects the copper structure 106 from corrosion during the singulation, assembly, wire bonding, and encapsulation operations.

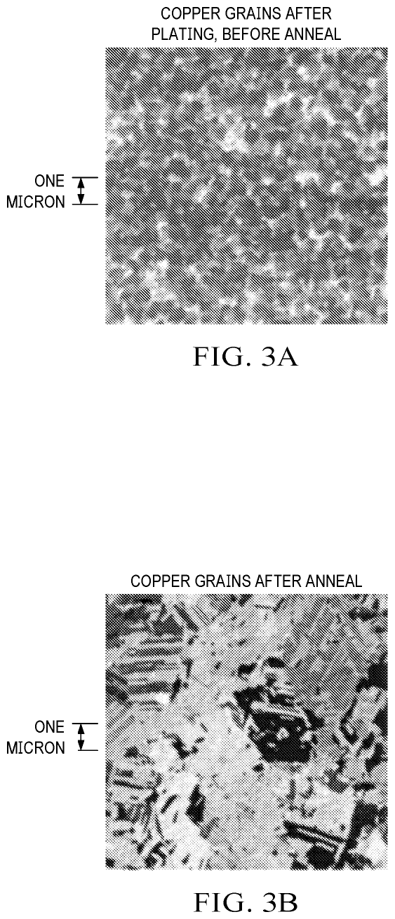

FIG. 3A and FIG. 3B are edge representations of microphotographs of electroplated copper, before and after annealing. FIG. 3A shows a first microphotograph of a sample of electroplated copper before annealing. An average grain size of the copper is less than 1 micron, as seen by comparison to the micron bar on the left of the first microphotograph.

FIG. 3B shows a second microphotograph of a sample of electroplated copper after annealing. An average grain size of the copper is greater than 1 micron, as seen by comparison to the micron bar on the left of the second microphotograph.

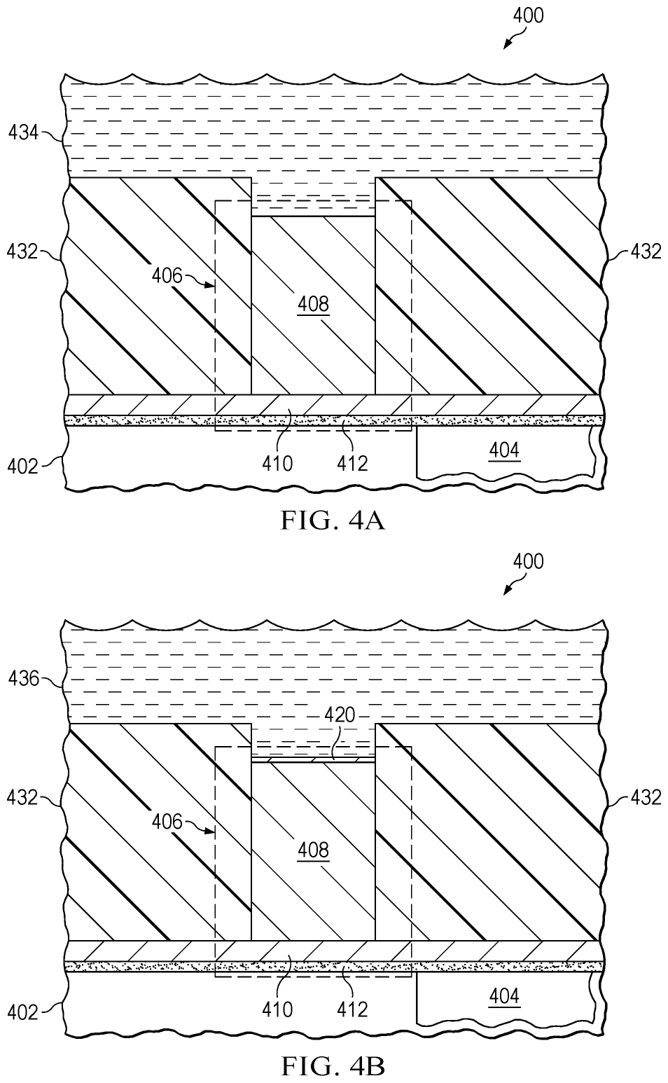

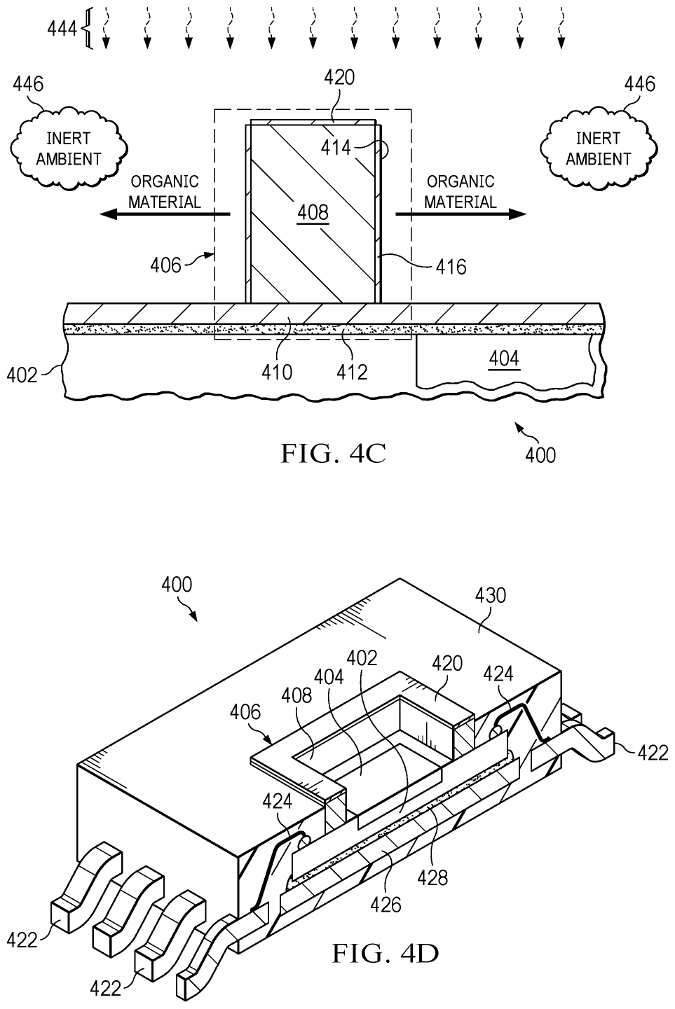

FIG. 4A through FIG. 4D are cross sections of another example microelectronic device, depicted in stages of another example method of formation. Referring to FIG. 4A, the microelectronic device 400 is formed on a substrate 402. The substrate 402 includes an electronic component 404. An adhesion layer 412 is formed on the substrate 402. A seed layer 410 is formed on the adhesion layer 412. A plating mask 432 is formed over the seed layer 410, exposing the seed layer 410 in an area for a copper structure 406.

The microelectronic device 400 is immersed in a copper plating bath 434 that includes copper ions and organic additives in an aqueous solution. Electric current is flowed from a copper anode, not specifically shown, through the copper plating bath 434, to the seed layer 410, causing copper to be electroplated in the area exposed by the plating mask 432, thereby forming a cavity enclosure 408 of the copper structure 406. As the copper is electroplated on the cavity enclosure 408, a portion of the organic additives are incorporated into the cavity enclosure 408 resulting in an average grain size of the copper that is less than 1 micron, and resulting in an average carbon content of the copper structure 406, immediately after plating the copper, that is more than 100 ppm by weight. In this example, electroplating the copper is terminated before the cavity enclosure 408 reaches a top surface of the plating mask 432. FIG. 4A depicts the cavity enclosure 408 at completion.

Referring to FIG. 4B, the microelectronic device 400 is immersed in a cap metal plating bath 436. The cap metal plating bath 436 includes metal ions, such as gold ions, platinum ions, palladium ions, or chromium ions. Electric current is flowed from an anode, not specifically shown, through the cap metal plating bath 436, to the cavity enclosure 408, causing cap metal, such as gold, platinum, palladium, or chromium, to be electroplated on the cavity enclosure 408, thereby forming a metal cap layer 420 of the copper structure 406.

After the metal cap layer 420 is formed, the plating mask 432 is removed. Subsequently, the seed layer 410 is removed where exposed by the cavity enclosure 408. The adhesion layer 412 is removed where exposed by the seed layer 410.

Referring to FIG. 4C, the microelectronic device 400 is subsequently exposed to air, after which a corrosion barrier 414 is present on the exposed surfaces 416 of the microelectronic device 400. The corrosion barrier 414 includes primarily cuprous oxide, and may be 0.5 nanometers to 2 nanometers thick.

The microelectronic device 400 is subsequently heated by an anneal process 444 to 125° C. to 200° C. for 20 minutes to 45 minutes in a non-reducing ambient 446, implemented as an inert ambient 446 in this example, as depicted schematically in FIG. 2I. The inert ambient 446 may be implemented as nitrogen, argon, or other gas that does not chemically react with copper.

During the anneal process 444, organic material, depicted schematically in FIG. 4C, in the cavity enclosure 408 diffuses out of the copper structure 406, into the inert ambient 446 causing an average carbon content of the copper structure 406 to drop from more than 100 ppm by weight to less than 20 ppm by weight, during the anneal process 444. An average grain size of the copper may grow from less than 1 micron to greater than 1 micron, during the anneal process 444.

The corrosion barrier 414 becomes more contiguous and more impermeable to moisture during the anneal process 444. Due to a lack of oxygen in the inert ambient 446, the corrosion barrier 414 may remain essentially constant in thickness at 0.5 nanometers to 2 nanometers.

Referring to FIG. 4D, the microelectronic device 400 is singulated. After singulation, the microelectronic device 400 is attached to a die pad 426 by a die attach material 428. Wire bonds 424 are formed, electrically connecting the substrate 402 to the leads 422. The encapsulation material 430 is formed on the substrate 402 and leads 422, surrounding the copper structure 406. The corrosion barrier 414 advantageously protects the copper structure 406 from corrosion during the singulation, assembly, wire bonding, and encapsulation operations.

Various features of the examples disclosed herein may be combined in other manifestations of example microelectronic devices. For example, the microelectronic device 100 of FIG. 2I may be formed by annealing in an inert ambient, as described in reference to FIG. 4C. The microelectronic device 400 of FIG. 4C may be formed by annealing in an oxidizing ambient, as described in reference to FIG. 2I. The microelectronic device 100 of FIG. 1A and FIG. 1B may be formed without a cap portion of the copper structure, as described in reference to FIG. 4A. The microelectronic device 400 of FIG. 4A and FIG. 4B may be formed with a cap portion of the copper structure, as described in reference to FIG. 2C. The microelectronic device 100 of FIG. 2D may be formed with a metal cap layer of a metal besides nickel, as described in reference to FIG. 4B. The microelectronic device 400 of FIG. 4B may be formed with a metal cap layer nickel, as described in reference to FIG. 2D.

While various embodiments of the present disclosure have been described above, it should be understood that they have been presented by way of example only and not limitation. Numerous changes to the disclosed embodiments can be made in accordance with the disclosure herein without departing from the spirit or scope of the disclosure. Thus, the breadth and scope of the present invention should not be limited by any of the above described embodiments. Rather, the scope of the disclosure should be defined in accordance with the following claims and their equivalents.

What is claimed is:

1. A microelectronic device, comprising:
an electronic component;
a copper structure over the electronic component, the copper structure including primarily copper having an average grain size greater than 1 micron; and
a corrosion barrier directly on the copper, the corrosion barrier including primarily cuprous oxide, wherein the corrosion barrier is exposed at an exterior surface of the microelectronic device.

2. The microelectronic device of claim 1, wherein the copper structure includes carbon distributed in the copper.

3. The microelectronic device of claim 2, wherein an average carbon content of the copper structure is less than 20 parts per million (ppm) by weight.

4. The microelectronic device of claim 1, wherein the corrosion barrier is 0.5 nanometers to 3 nanometers thick.

5. The microelectronic device of claim 1, wherein the copper structure includes a metal cap layer on the copper.

6. The microelectronic device of claim 5, wherein the metal cap layer includes primarily nickel.

7. The microelectronic device of claim 1, wherein the electronic component is a sensor component.

8. The microelectronic device of claim 1, wherein the copper structure includes a cap portion that extends laterally past vertical sidewalls of the copper structure.

9. The microelectronic device of claim 1, further including encapsulation material contacting the copper structure.

10. A method of forming a microelectronic device, comprising:
plating copper over a substrate of the microelectronic device to form a copper structure;
annealing the copper structure, the copper structure including a corrosion barrier including primarily cuprous oxide directly on the copper, at a temperature of 125° C. to 200° C. in a non-reducing ambient; and
packaging the substrate and the copper structure, wherein the corrosion barrier is exposed at an exterior surface of the microelectronic device.

11. The method of claim 10, wherein plating the copper is performed using a plating bath that includes organic additives.

12. The method of claim 11, wherein the copper structure includes carbon distributed in the copper.

13. The method of claim 12, wherein an average carbon content of the copper structure after plating the copper, prior to annealing the copper structure, is more than 100 parts per million (ppm) by weight.

14. The method of claim 12, wherein an average carbon content of the copper structure after annealing the copper structure is less than 20 ppm by weight.

15. The method of claim 12, wherein annealing the copper structure removes a portion of the carbon from the copper.

16. The method of claim 10, wherein an average grain size of the copper is less than 1 micron, prior to annealing the copper structure.

17. The method of claim 10, wherein an average grain size of the copper is greater than 1 micron, after annealing the copper structure.

18. The method of claim 10, wherein the corrosion barrier is 0.5 nanometers to 3 nanometers thick after annealing the copper structure.

19. The method of claim 10, wherein the copper structure is annealed for 20 minutes to 45 minutes.

20. The method of claim 10, wherein the non-reducing ambient includes oxygen.
